(19) United States
(12) Patent Application Publication
(10) Pub. No.: US 2018/0183451 A1
(43) Pub. Date: Jun. 28, 2018

(54) MULTIPLE RESISTOR STRING DIGITAL-TO-ANALOG (DAC) CONVERTER HAVING IMPROVED SWITCHING NOISE

(71) Applicant: SAMSUNG ELECTRO-MECHANICS CO., LTD., Suwon-si (KR)

(72) Inventors: Soo Woong LEE, Suwon-si (KR); Joo Yul KO, Suwon-si (KR); Woo Young CHOI, Suwon-si (KR)

(73) Assignee: SAMSUNG ELECTRO-MECHANICS CO., LTD., Suwon-si (KR)

(21) Appl. No.: 15/705,583

(22) Filed: Sep. 15, 2017

(30) Foreign Application Priority Data
Dec. 26, 2016 (KR) 10-2016-0179511

(51) Int. Cl. H03M 1/08

(52) U.S. Cl. CPC H03M 1/0863

(57) ABSTRACT

A multiple resistor string digital-to-analog converter (DAC) includes a first resistor string circuit including first through n-th resistors, where n is a natural number; a first switching circuit connected between one terminal of each of the first through n-th resistors and a first connection node, and configured to select one terminal of a corresponding k-th resistor, where k is a natural number equal to or greater than 1 and equal to or smaller than n, of the first resistor string circuit based on a digital code; a second switching circuit connected to the other terminal of the first through n-th resistors, and configured to select the other terminal of the corresponding k-th resistor of the first resistor string circuit depending on the digital code; and a third switching circuit configured to select a voltage divided by the resistors of the second resistor string circuit depending on the digital code.

### CROSS-REFERENCE TO RELATED APPLICATION(S)

This application claims benefit of priority under 35 USC 119(a) of Korean Patent Application No. 10-2016-0179511 filed on Dec. 26, 2016 in the Korean Intellectual Property Office, the disclosure of which is incorporated herein by reference for all purposes.

### BACKGROUND

### 1. Field

The present disclosure relates to a multiple resistor string digital-to-analog (DAC) converter in a camera module.

### 2. Description of Related Art

Generally, a digital to analog converter (DAC) converts discontinuous digital bits into a continuous analog signal. Recently, as mobile devices, such as mobile phones, have increasingly been implemented to have high performance, a high performance analog-to-digital converter (ADC) and a DAC may be required.

Typically, a multiple resistor string DAC has been used to simultaneously satisfy monotonic growth and high resolution performance.

The typical multiple resistor string DAC may generate switching noise every time it operates. However, an image sensor, a hall sensor, or the like in a camera module are very sensitive to noise.

The existing multiple resistor string DAC may include first and second resistor strings in two stages, an upper buffer and a lower buffer connected between the first and second resistor strings, and an output buffer connected between the second resistor string and an output terminal.

For example, the first resistor string may correspond to most significant bit (MSB) 2 bits and the second resistor string may correspond to least significant bit (LSB) 2 bits. The first resistor string may be divided into four stages and the second resistor string may divide one stage of the first resistor string into four stages again, such that data of all sixteen stages may be output.

Here, when locations of the upper buffer and the lower buffer are changed, depending on the code during a code conversion process of a digital signal into an analog signal, the existing multiple resistor string DAC may cause switching noise when the locations of the upper buffer and the lower buffer are changed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, resistor string circuit includes resistors connected in series between an output terminal a multiple resistor string digital-to-analog converter (DAC) includes a first resistor string circuit, a first switching circuit, a second switching circuit, a first buffer, a second buffer, a second resistor string circuit, and a third switching circuit. The first resistor string circuit includes first through n-th resistors, where n is a natural number equal to or greater than 1, connected in series between a terminal supplied with a first voltage and a ground. The first switching circuit is connected between one terminal of each of the first through n-th resistors and a first connection node, and configured to select one terminal of a corresponding k-th resistor, where k is a natural number equal to or greater than 1 and equal to or smaller than n, of the first resistor string circuit depending on a digital code. The second switching circuit is connected to the other terminal of the first through n-th resistors and a second connection node, and configured to select the other terminal of the corresponding k-th resistor of the first resistor string circuit depending on the digital code. The first buffer has an input terminal connected to the first connection node. The second buffer has an input terminal connected to the second connection node. The second of the first buffer and an output terminal of the second buffer. The third switching circuit is configured to select a voltage divided by the resistors of the second resistor string circuit depending on the digital code.

The first switching circuit may include upper switches configured to select one terminal of the corresponding k-th resistor of the first through n-th resistors of the first resistor string circuit depending on corresponding most significant bit (MSB) bits of the digital code.

The second switching circuit may include lower switches configured to select the other terminal of the corresponding k-th resistor of the first through n-th resistors of the first resistor string circuit depending on corresponding most significant bit (MSB) bits of the digital code.

The first switching circuit may select one terminal of the corresponding k-th resistor of the first through n-th resistors of the first resistor string circuit depending on corresponding MSB bits of the digital code, and the second switching circuit may select the other terminal of the corresponding k-th resistor depending on the corresponding MSB bits.

The third switching circuit may include switches configured to select the corresponding resistor of the resistors of the second resistor string circuit depending on corresponding least significant bit (LSB) bits of the digital code.

In another general aspect, a multiple resistor string digital-to-analog converter (DAC) includes a first resistor string circuit, a first switching circuit, a second switching circuit, a first buffer, a second buffer, a second resistor string circuit, a third switching circuit, and an output buffer. The first resistor string circuit includes first through n-th resistors, where n is a natural number equal to or greater than 1, connected in series between a terminal supplied with a first voltage and a ground. The first switching circuit is connected between one terminal of each of the first through n-th resistors and a first connection node, and includes upper switches configured to select one terminal of a corresponding k-th resistor, where k is a natural number equal to or greater than 1 and equal to or smaller than n, depending on upper bits a digital code. The second switching circuit is connected to the other terminal of each of the first through n-th resistors and a second connection node, and includes lower switches configured to select the other terminal of the corresponding k-th resistor of the first resistor string circuit depending on the upper bits of the digital code. The first buffer has an input terminal connected to the first connection node. The second buffer has an input terminal connected to the second connection node. The second resistor string circuit includes resistors connected in series between an output terminal of the first buffer and an output terminal of the second buffer. The third switching circuit includes switches configured to select a voltage divided by resistors of the second resistor string circuit depending on lower bits the digital code. The output buffer connected between the third switching circuit and an output terminal.

The first switching circuit may select one terminal of the corresponding k-th resistor of the first through n-th resistors of the first resistor string circuit depending on corresponding MSB bits of the digital code.

The second switching circuit may select the other terminal of the corresponding k-th resistor of the first through n-th resistors of the first resistor string circuit depending on corresponding MSB bits of the digital code.

The first switching circuit may select one terminal of the corresponding k-th resistor of the first through n-th resistors of the first resistor string circuit depending on corresponding MSB bits of the digital code, and the second switching circuit may select the other terminal of the corresponding k-th resistor depending on the corresponding MSB bits.

The third switching circuit may connect between one terminal of the corresponding resistor of the resistors of the second resistor string circuit depending on corresponding least significant bit (LSB) bits of the digital code and an output terminal.

A mobile device may include the multiple resistor string DAC.

In another general aspect, a multiple resistor string digital-to-analog converter (DAC) comprises a first resistor string circuit comprising resistors connected in series between a terminal supplied with a first voltage and a ground voltage; a first switching circuit connected between a first subset of terminals of the resistors and a first buffer, and configured to select terminals corresponding to a digital code from the first subset of terminals; a second switching circuit connected to a second subset of terminals and a second buffer, and configured to select terminals corresponding to the digital code from the second subset of terminals; a second resistor string circuit comprising resistors connected in series between an output terminal of the first buffer and an output terminal of the second buffer; and a third switching circuit configured to select a voltage divided by the resistors of the second resistor string circuit depending on the digital code.

The first switching circuit may include upper switches configured to select corresponding terminals of the first subset of terminals based on most significant bit (MSB) bits of the digital code.

The second switching circuit may include lower switches configured to select corresponding terminals of the second subset of terminals based on most significant bit (MSB) bits of the digital code.

The third switching circuit may include switches configured to select the corresponding resistor of the resistors of the second resistor string circuit depending on corresponding least significant bit (LSB) bits of the digital code.

Other features and aspects will be apparent from the following detailed description, the drawings, and the claims.

### BRIEF DESCRIPTION OF DRAWINGS

FIG. 1 is an example of a multiple resistor string digital-to-analog (DAC) converter.

FIG. 2 is another example of a multiple resistor string digital-to-analog (DAC) converter.

FIG. 3 is an example of one operation of the multiple resistor string digital-to-analog (DAC) converter.

FIG. 4 is another example of another operation of the multiple resistor string digital-to-analog (DAC) converter.

FIG. 5 is a graph illustrating a noise power spectral density (PSD) and the effective number of bits (ENOB) of the existing multiple resistor string digital-to-analog (DAC) converter.

FIG. 6 is a graph illustrating a noise power spectral density (PSD) and the effective number of bits (ENOB) of a multiple resistor string digital-to-analog (DAC) converter according to an example in the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application.

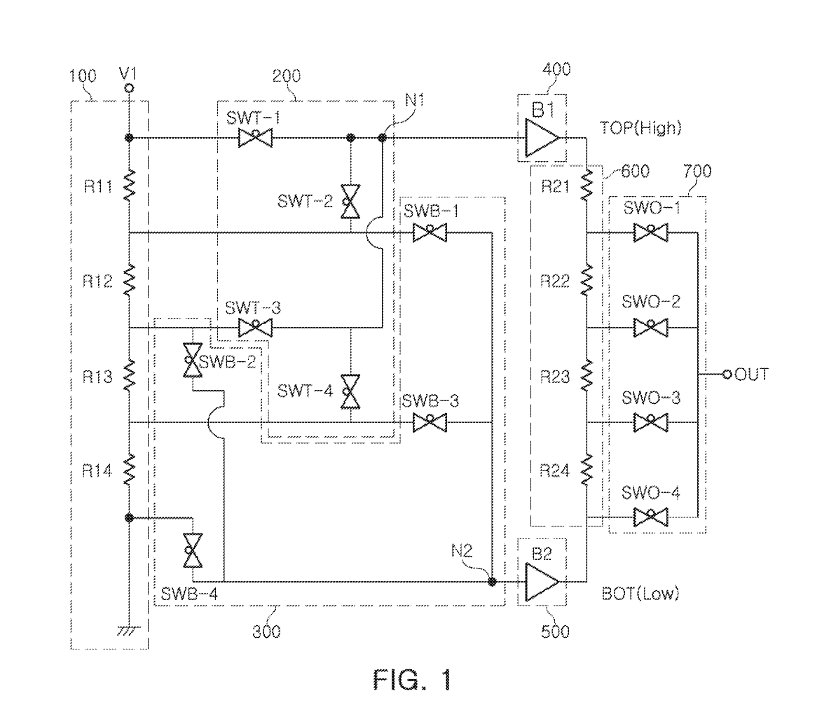

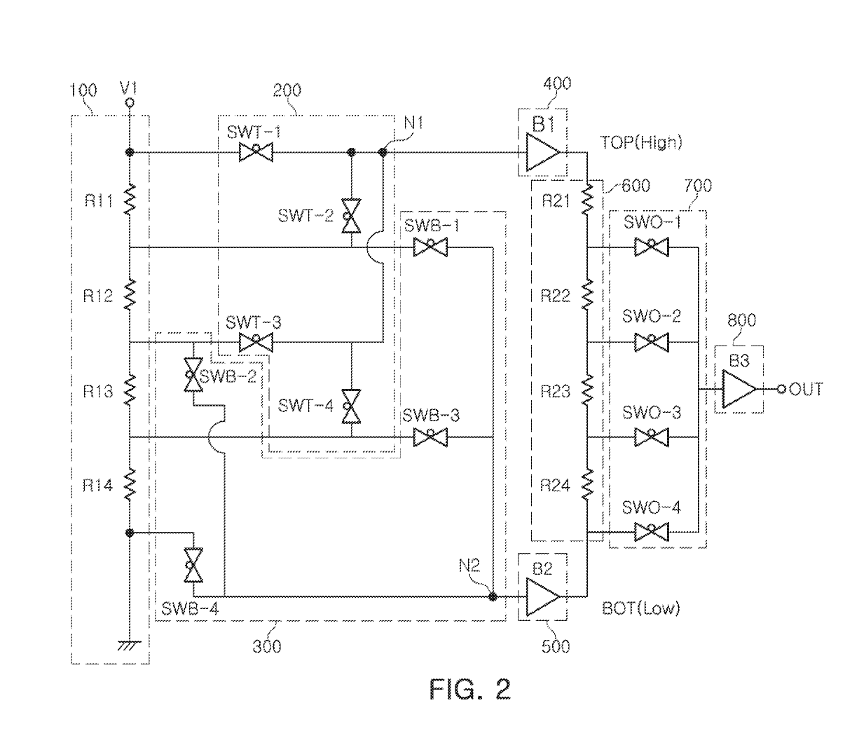

Referring to FIGS. 1 and 2, a multiple resistor string digital-to-analog (DAC) converter according to an example in the present disclosure includes a first resistor string circuit 100, a first switching circuit 200, a second switching circuit 300, a first buffer 400, a second buffer 500, a second resistor string circuit 600, and a third switching circuit 700.

Referring to FIG. 2, the multiple resistor string digital-to-analog (DAC) converter further includes an output buffer 800.

Referring to FIGS. 1 and 2, the first resistor string circuit 100 includes first through n-th resistors connected between a terminal to which a first voltage V1 is supplied and a ground in series, in which n may be a natural number equal to or greater than 1.

For example, as illustrated in FIGS. 1 and 2, the first resistor string circuit 100 includes first through fourth resistors R11 through R14, but in FIGS. 1 and 2, n=4 is illustrated; however, the value of n is not limited thereto.

The first switching circuit 200 is connected between one terminal of each of the first through fourth resistors R11 through R14 and a first connection node N1 and selects one terminal of the corresponding k-th resistor, where k is a natural number equal to or greater than 1 and equal to or smaller than n, of the first resistor string circuit 100 depending on a digital code.

For example, the first switching circuit 200 includes a plurality of top switches SWT-1 to SWT-4 that selects one terminal of the corresponding k-th resistor among the first through fourth resistors R11 through R14 of the first resistor string circuit 100 depending on most significant bit (MSB) bits of the digital code.

Hereinafter, in the following description of the present disclosure, n=4 is described for convenience and ease of understanding, but this does not mean that the description is limited to n=4.

For example, when the first resistor string circuit 100 includes four first through fourth resistors R11 through R14, the corresponding MSB bits of the digital code is the MSB 2 bits, and in the corresponding k-th resistors, k is a natural number of 1 to 4.

For example, when the top switch is configured of four switches SWT-1 to SWT-4, the SWT-1 switch selects one terminal of the first resistor R11, the SWT-2 switch selects one terminal of the second resistor R12, the SWT-3 switch selects one terminal of the third resistor R13, and the SWT-4 switch selects one terminal of the fourth resistor R14.

The second switching circuit 300 is connected between the other terminal of each of the first through fourth resistors R11 through R14 and a second connection node N2 and includes a plurality of bottom switches selecting the other terminal of the corresponding k-th resistor of the first resistor string circuit 100 depending on the digital code.

For example, when the bottom switch is configured of four switches SWB-1 to SWB-4, the SWB-1 switch selects the other terminal of the first resistor R11, the SWB-2 switch selects the other terminal of the second resistor R12, the SWB-3 switch selects the other terminal of the third resistor R13, and the SWB-4 switch selects the other terminal of the fourth resistor R14.

According to the foregoing description, the first switching circuit 200 selects one terminal of the corresponding k-th resistor among the first through fourth resistors R11 through R14 of the first resistor string circuit 100 depending on the corresponding MSB 2 bits of the digital code and the second switching circuit 300 selects the other terminal of the corresponding k-th resistor depending on the corresponding MSB 2 bits.

For example, the first switching circuit 200 selects one terminal of the first resistor R11 of the first through fourth resistors R11 through R14 of the first resistor string circuit 100 depending on the corresponding MSB 2 bits of the digital code and the second switching circuit 300 selects the other terminal of the corresponding first resistor R11 depending on the corresponding MSB 2 bits.

As another example, the first switching circuit 200 selects one terminal of the second resistor R12 of the first through fourth resistors R11 through R14 of the first resistor string circuit 100 depending on the corresponding MSB 2 bits of the digital code and the second switching circuit 300 selects the other terminal of the corresponding second resistor R12 depending on the corresponding MSB 2 bits.

As another example, the first switching circuit 200 selects one terminal of the third resistor R13 of the first through fourth resistors R11 through R14 of the first resistor string circuit 100 depending on the corresponding MSB 2 bits of the digital code and the second switching circuit 300 selects the other terminal of the corresponding third resistor R13 depending on the corresponding MSB 2 bits.

As another example, the first switching circuit 200 selects one terminal of the fourth resistor R14 of the first through fourth resistors R11 through R14 of the first resistor string circuit 100 depending on the corresponding MSB 2 bits of the digital code and the second switching circuit 300 selects the other terminal of the corresponding fourth resistor R14 depending on the corresponding MSB 2 bits.

Unlike the related art, as described above, the first buffer and the second buffer do not change their top and bottom locations at the time of the code change. That is, the first buffer is in the top location all the times, the second buffer is in the bottom location all the times, and therefore the switch noise occurring due to a reversal of the locations of the first and second buffers is improved.

The first buffer 400 includes an input terminal connected to the first connection node N1 to transmit the highest voltage selected by the first switching circuit 200 to the second resistor string circuit 600.

Further, the second buffer 500 includes an input terminal connected to the second connection node N2 to transmit the lowest voltage selected by the second switching circuit 300 to the second resistor string circuit 600.

The second resistor string circuit 600 includes a plurality of resistors R21 through R24 connected between an output terminal of the first buffer 400 and an output terminal of the second buffer 500 in series.

For example, when the second resistor string circuit 600 includes the four resistors R21 through R24, the second resistor string circuit 600 uses the four resistors R21 through R24 to divide a difference voltage between the highest voltage of the output terminal of the first buffer 400 and the lowest voltage of the output terminal of the second buffer 500.

The third switching circuit 700 includes a plurality of switches and may include, for example, four switches SWO-1 to SWO-4.

For example, when the difference voltage between the highest voltage of the output terminal of the first buffer 400 and the lowest voltage of the output terminal of the second buffer 500 is divided by the four resistors R21 through R24 of the second resistor string circuit 600, the four switches SWO-1 to SWO-4 select one of voltages divided by the four resistors R21 through R24 of the second resistor string circuit 600 depending on the digital code.

Referring to FIG. 2, the output buffer 800 is connected between the third switching circuit 700 and an output terminal OUT to output a voltage selected by the third switching circuit 700 through the output terminal OUT.

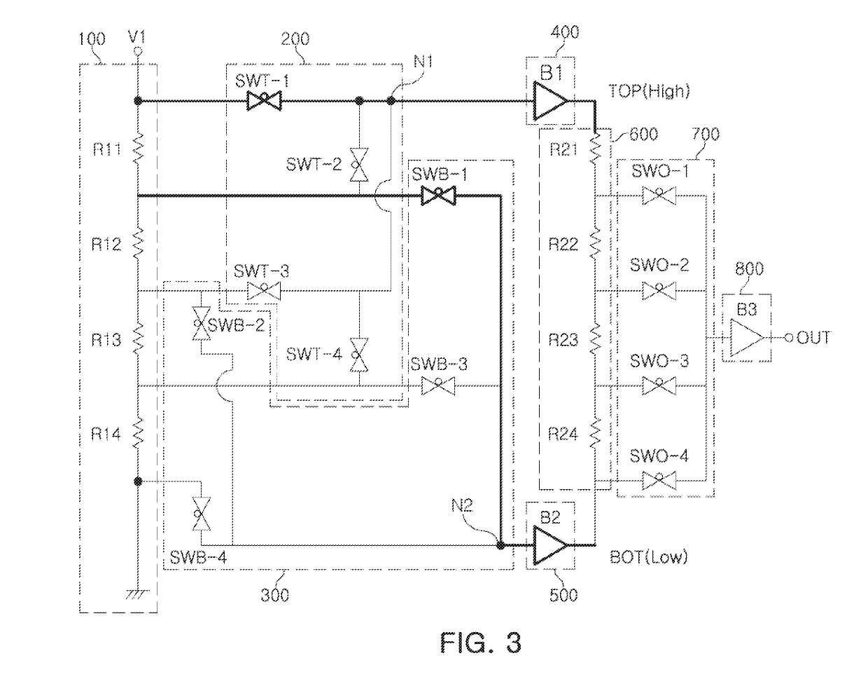

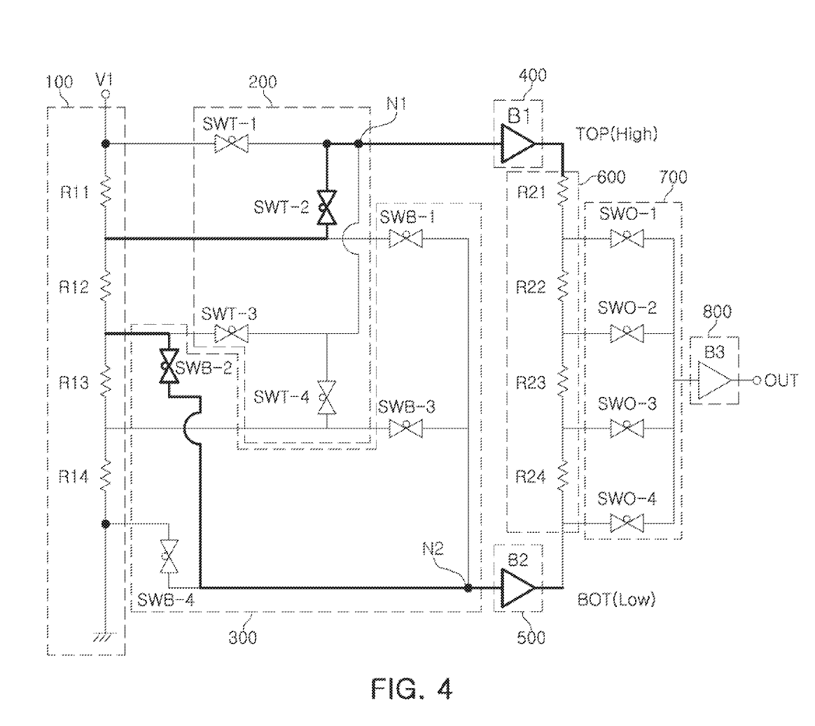

Hereinafter, the case in which the digital code is a 4-bit code consisting of the MSB 2 bits and LSB 2 bits will be described with reference to FIGS. 3 and 4.

FIG. 3 is an example of one operation of the multiple resistor string digital-to-analog (DAC) converter.

Referring to FIG. 3, when the digital code is 1100, the top switch SWT-1 of the first switching circuit 100 is turned on depending on the MSB 2 bits “11”, and the bottom switch SWB-1 of the second switching circuit 200 is turned on, such that a voltage across the first resistor R11 of the first resistor string circuit 100 is selected. The voltage across the first resistor R11 is re-divided by the second resistor string circuit 600.

Then, the switch SWO-4 of the second switching circuit 700 is turned on depending on LSB 2 bit “00” of the digital code 1100, such that the voltage output through the second buffer 500 is output through the output terminal OUT via the output buffer 800.

FIG. 4 is another example another operation of the multiple resistor string digital-to-analog (DAC) converter according to the example in the present disclosure.

Referring to FIG. 4, when the digital code is 1011, the top switch SWT-2 of the first switching circuit 100 is turned on depending on MSB 2 bits “10”, and the bottom switch SWB-2 of the second switching circuit 200 is turned on, such that the voltage across the first resistor R12 of the first resistor string circuit 100 is selected. The voltage across the second resistor R12 is re-divided by the second resistor string circuit 600.

Next, the switch SWO-1 of the second switching circuit 700 is turned on depending on LSB 2 bits “11” of digital code 1011, such that the difference voltage between the highest voltage of the output terminal of the first buffer 400 and the lowest voltage of the output terminal of the second buffer 500 is divided into the three resistors R22 through R24 of the four resistors R21 through R24, and the divided voltage is output through the output terminal OUT via the output buffer 800.

As another example, when the digital code is 0100, the top switch SWT-3 of the first switching circuit 100 is turned on and the bottom switch SWB-3 of the second switching circuit 200 is turned on, such that a voltage across the third resistor R13 of the first resistor string circuit 100 is selected. The voltage across the third resistor R13 is re-divided by the second resistor string circuit 600.

Subsequently, the switch SWO-1 of the second switching circuit 700 is turned on depending on LSB 2 bits “00” of digital code 0100, such that the voltage output through the second buffer 500 is output through the output terminal OUT via the output buffer 800.

As another example, when the digital code is 0011, the top switch SWT-4 of the first switching circuit 100 is turned on and the bottom switch SWB-4 of the second switching circuit 200 is turned on, such that a voltage across the fourth resistor R14 of the first resistor string circuit 100 is selected. The voltage across the fourth resistor R14 is re-divided by the second resistor string circuit 600.

Next, the switch SWO-1 of the second switching circuit 700 is turned on depending on the LSB 2 bits “11” of the digital code 0011, such that the difference voltage between the highest voltage of the output terminal of the first buffer 400 and the lowest voltage of the output terminal of the second buffer 500 is divided into the three resistors R22 through R24 of the four resistors R21 through R24, and the divided voltage is output through the output terminal OUT via the output buffer 800.

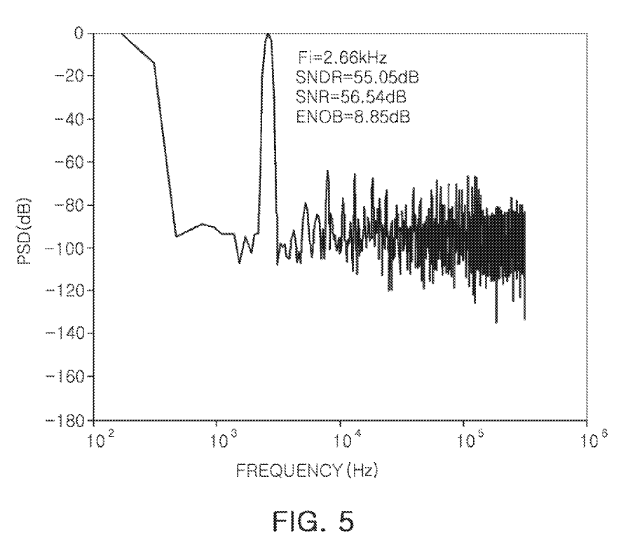

FIG. 5 is a graph illustrating a noise power spectral density (PSD) and the effective number of bits (ENOB) of the existing multiple resistor string digital-to-analog (DAC) converter.

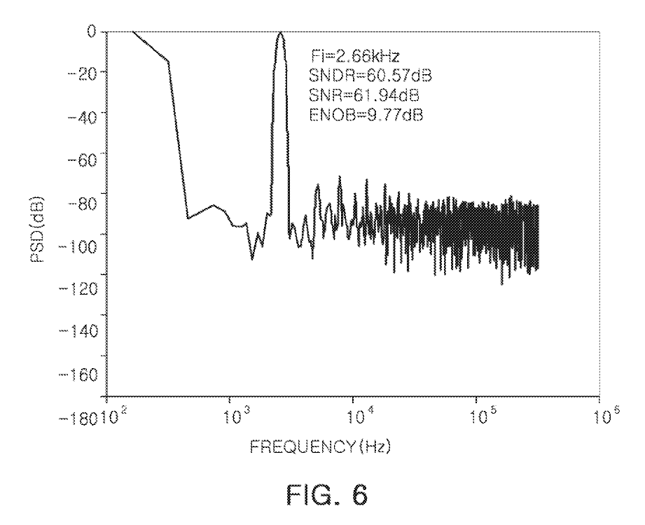

FIG. 6 is a graph illustrating a noise power spectral density (PSD) and the effective number of bits (ENOB) of a multiple resistor string digital-to-analog (DAC) converter according to an example in the present disclosure. FIGS. 5 and 6 also list obtained values for the signal-to-noise ratio (SNR) and the signal-to-noise distortion ratio (SNDR).

Referring to the graph depicted in FIGS. 5 and 6, it is appreciated that the ENOB related to the switching noise of the buffer output generated at the time of the switching of the first resistor string circuit in the multiple resistor string affecting ENOB (effective bit numbers) characteristics of the digital-to-analog (DAC) converter is improved by approximately 0.9 dB.

As set forth above, according to the examples in the present disclosure, the switching noise is efficiently improved by using the simple switch structure.

As a non-exhaustive example only, a device as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device configured to perform wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. A multiple resistor string digital-to-analog converter (DAC), comprising:
a first resistor string circuit comprising first through n-th resistors, where n is a natural number equal to or greater than 1, connected in series between a terminal supplied with a first voltage and a ground voltage;
a first switching circuit connected between one terminal of each of the first through n-th resistors and a first connection node, and configured to select one terminal of a corresponding k-th resistor, where k is a natural number equal to or greater than 1 and equal to or smaller than n, of the first resistor string circuit;
a second switching circuit connected to another terminal of each of the first through n-th resistors and a second connection node, and configured to select another terminal of the corresponding k-th resistor of the first resistor string circuit;
a second resistor string circuit comprising resistors connected in series; and
a third switching circuit configured to select a voltage divided by the resistors of the second resistor string circuit.

2. The multiple resistor string DAC of claim 1, wherein the first switching circuit comprises upper switches configured to select one terminal of the corresponding k-th resistor of the first through n-th resistors of the first resistor string circuit based on corresponding most significant bit (MSB) bits of a digital code.

3. The multiple resistor string DAC of claim 1, wherein the second switching circuit comprises lower switches configured to select the other terminal of the corresponding k-th resistor of the first through n-th resistors of the first resistor string circuit based on corresponding most significant bit (MSB) bits of a digital code.

4. The multiple resistor string DAC of claim 1, wherein the first switching circuit selects one terminal of the corresponding k-th resistor of the first through n-th resistors of the first resistor string circuit based on corresponding MSB bits of a digital code, and the second switching circuit selects the other terminal of the corresponding k-th resistor based on the corresponding MSB bits.

5. The multiple resistor string DAC of claim 1, wherein the third switching circuit comprises switches configured to select the corresponding resistor of the resistors of the second resistor string circuit based on corresponding least significant bit (LSB) bits of a digital code.

6. The multiple resistor string DAC of claim 1, wherein a first buffer having an input terminal is connected to the first connection node.

7. The multiple resistor string DAC of claim 6, wherein a second buffer having an input terminal is connected to the second connection node and the resistors of the second resistor string circuit are connected in series between an output terminal of the first buffer and an output terminal of the second buffer.

8. A multiple resistor string digital-to-analog converter (DAC), comprising:
a first resistor string circuit comprising first through n-th resistors, where n is a natural number equal to or greater than 1, connected in series between a terminal supplied with a first voltage and a ground;
a first switching circuit connected between one terminal of each of the first through n-th resistors and a first connection node, and comprising upper switches configured to select one terminal of a corresponding k-th resistor, where k is a natural number equal to or greater than 1 and equal to or smaller than n, based on upper bits a digital code;
a second switching circuit connected to another terminal of each of the first through n-th resistors and a second connection node, and comprising lower switches configured to select another terminal of the corresponding k-th resistor of the first resistor string circuit based on the upper bits of the digital code;
a second resistor string circuit comprising resistors connected in series;
a third switching circuit comprising switches configured to select a voltage divided by resistors of the second resistor string circuit based on lower bits the digital code; and
an output buffer connected between the third switching circuit and an output terminal.

9. The multiple resistor string DAC of claim 8, wherein a first buffer having an input terminal is connected to the first connection node.

10. The multiple resistor string DAC of claim 9, wherein a second buffer having an input terminal is connected to the second connection node and the resistors of the second resistor string circuit are connected in series between an output terminal of the first buffer and an output terminal of the second buffer.

11. The multiple resistor string DAC of claim 8, wherein the first switching circuit selects one terminal of the corresponding k-th resistor of the first through n-th resistors of the first resistor string circuit based on corresponding MSB bits of the digital code.

12. The multiple resistor string DAC of claim 8, wherein the second switching circuit selects the other terminal of the corresponding k-th resistor of the first through n-th resistors of the first resistor string circuit based on corresponding MSB bits of the digital code.

13. The multiple resistor string DAC of claim 8, wherein the first switching circuit selects one terminal of the corresponding k-th resistor of the first through n-th resistors of the first resistor string circuit based on corresponding MSB bits of the digital code, and the second switching circuit selects the other terminal of the corresponding k-th resistor based on the corresponding MSB bits.

14. The multiple resistor string DAC of claim 8, wherein the third switching circuit connects between one terminal of the corresponding resistor of the resistors of the second resistor string circuit based on corresponding least significant bit (LSB) bits of the digital code and an output terminal.

15. A multiple resistor string digital-to-analog converter (DAC), comprising:
a first resistor string circuit comprising resistors connected in series between a terminal supplied with a first voltage and a ground;
a first switching circuit connected between one terminal of each of the resistors of the first resistor string circuit and a first buffer, and configured to select terminals of the resistors of the first resistor string circuit corresponding to a digital code;
a second switching circuit connected to another terminal of each of the resistors of the first resistor string circuit and a second buffer, and configured to select terminals of the resistors of the first resistor string circuit corresponding to the digital code;
a second resistor string circuit comprising resistors connected in series between an output terminal of the first buffer and an output terminal of the second buffer; and
a third switching circuit configured to select a voltage divided by the resistors of the second resistor string circuit based on the digital code.

16. The multiple resistor string DAC of claim 15, wherein the first switching circuit comprises upper switches configured to select corresponding terminals of the resistors of the first resistor string circuit based on most significant bit (MSB) bits of the digital code.

17. The multiple resistor string DAC of claim 15, wherein the second switching circuit comprises lower switches configured to select corresponding terminals of the resistors of the first resistor string circuit based on most significant bit (MSB) bits of the digital code.

18. The multiple resistor string DAC of claim 15, wherein the third switching circuit comprises switches configured to select the corresponding resistor of the resistors of the second resistor string circuit based on corresponding least significant bit (LSB) bits of the digital code.
